(19) United States
(12) Patent Application Publication
(10) Pub. No.: US 2021/0249238 A1
(43) Pub. Date: Aug. 12, 2021

(54) EXHAUST PIPE DEVICE

(71) Applicant: Kioxia Corporation, Tokyo (JP)

(72) Inventors: Hiroshi MATSUBA, Fujisawa Kanagawa (JP); Akihiro OISHI, Yokohama Kanagawa (JP); Hiroyuki FUKUMIZU, Yokohama Kanagawa (JP); Kazuaki KURIHARA, Yokkaichi Mie (JP)

(73) Assignee: Kioxia Corporation, Tokyo (JP)

(21) Appl. No.: 17/021,476

(22) Filed: Sep. 15, 2020

(30) Foreign Application Priority Data
Feb. 7, 2020 (JP) 2020-019685

(51) Int. Cl. H01J 37/32; C23C 16/44

(52) U.S. Cl. CPC H01J 37/32834; H01J 37/32082; H01J 2237/335; H01J 2237/002; C23C 16/4412

(57) ABSTRACT

An exhaust pipe device according to an embodiment includes a pipe body, a coil, an inner pipe, and a plasma generation circuit. The coil is disposed inside the pipe body. The inner pipe is a dielectric and is disposed inside the coil. The plasma generation circuit is configured to generate plasma inside the inner pipe using the coil. The exhaust pipe device functions as a part of an exhaust pipe disposed between a film forming chamber and a vacuum pump for exhausting an inside of the film forming chamber.

### CROSS-REFERENCE TO RELATED APPLICATION

This application is based upon and claims the benefit of priority from Japanese Patent Application No. 2020-019685 filed on Feb. 7, 2020 in Japan, the entire contents of which are incorporated herein by reference.

### FIELD

Embodiments described herein relate generally to an exhaust pipe device.

### BACKGROUND

In a film forming apparatus represented by a chemical vapor deposition (CVD) apparatus, raw material gas is introduced into a film forming chamber, and a desired film is formed on a substrate disposed in the film forming chamber. Then, the raw material gas remaining in the film forming chamber is exhausted by a vacuum pump via an exhaust pipe. At that time, products resulting from the raw material gas may be deposited in the exhaust pipe to close the exhaust pipe, or the products may be deposited in the vacuum pump on the downstream side of the exhaust pipe to stop the vacuum pump. To remove the deposited products, cleaning processing is performed by a remote plasma source (RPS) device. However, since the RPS device generally focuses on cleaning in the film forming chamber, cleaning performance is insufficient to clean the products deposited in the exhaust pipe near the vacuum pump distant from the

RPS device and the vacuum pump.

### BRIEF DESCRIPTION OF THE DRAWINGS

FIG. 1 is a configuration diagram showing an example of a configuration of an exhaust system of a semiconductor manufacturing apparatus in a first embodiment;

FIG. 2 is a cross-sectional view of an example of an exhaust pipe device in the first embodiment when viewed from a front direction;

FIG. 3 is a cross-sectional view of an example of the exhaust pipe device in the first embodiment when viewed from a top surface direction;

FIG. 4 is a front view of an example of an exhaust pipe device in a comparative example of the first embodiment;

FIG. 5 is a cross-sectional view of an example of an exhaust pipe device in a second embodiment when viewed from a front direction;

FIG. 6 is a cross-sectional view of an example of an exhaust pipe device in a third embodiment when viewed from a front direction; and

FIG. 7 is a cross-sectional view of an example of an exhaust pipe device in a fourth embodiment when viewed from a front direction.

### DETAILED DESCRIPTION

An exhaust pipe device according to an embodiment includes a pipe body, a coil, an inner pipe, and a plasma generation circuit. The coil is disposed inside the pipe body. The inner pipe is a dielectric and is disposed inside the coil. The plasma generation circuit is configured to generate plasma inside the inner pipe using the coil. The exhaust pipe device functions as a part of an exhaust pipe disposed between a film forming chamber and a vacuum pump for exhausting an inside of the film forming chamber.

In the following embodiments, an exhaust pipe device capable of removing products deposited in an exhaust pipe near a vacuum pump will be described.

### First Embodiment

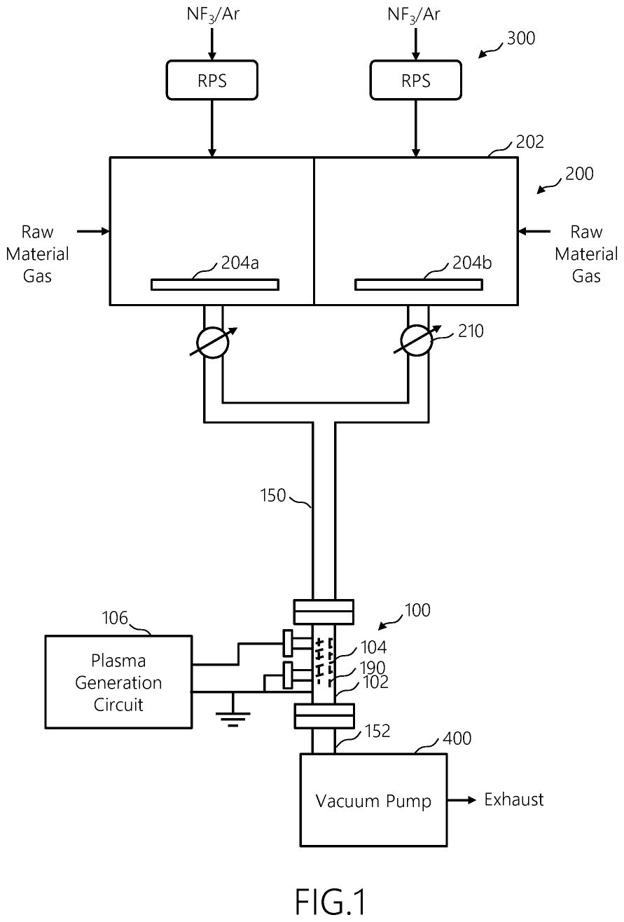

FIG. 1 is a configuration diagram showing an example of a configuration of an exhaust system of a semiconductor manufacturing apparatus in a first embodiment. In the example of FIG. 1, a film forming apparatus, for example, a chemical vapor deposition (CVD) apparatus 200 is shown as the semiconductor manufacturing apparatus. In the example of FIG. 1, a multi-chamber type CVD apparatus 200 in which two film forming chambers 202 are disposed is shown. In the CVD apparatus 200, semiconductor substrates 204 (204a and 204b) to be film-formed are disposed in the film forming chambers 202 controlled to a desired temperature. Then, evacuation is performed through exhaust pipes 150 and 152 by a vacuum pump 400, and raw material gas is supplied to the inside of the film forming chamber 202 controlled to a desired pressure by a pressure control valve 210. In the film forming chamber 202, a desired film is formed on the substrate 204 by a chemical reaction of the raw material gas. For example, a silicon oxide film (SiO film) or a silicon nitride film (SiN film) is formed by introducing silane (SiH₄) gas as main raw material gas. In addition, for example, tetraethoxysilane (TEOS) gas or the like is introduced as main raw material gas to form a silicon oxide film (SiO film). When these films are formed, products resulting from the raw material gas are deposited in the film forming chamber 202 and the exhaust pipes 150 and 152. Therefore, in a film forming process cycle, a cleaning step is performed in addition to a film forming step.

In the cleaning step, cleaning gas such as nitrogen trifluoride (NF₃) gas or purge gas such as argon (Ar) gas is supplied to remote plasma source (RPS) devices 300 disposed on the upstream side of the film forming chambers 202, and fluorine (F) radicals are generated by plasma. Then, by supplying (diffusing) the F radicals to the inside of the film forming chamber 202 and the side of the exhaust pipe 150, cleaning of the deposited products is performed. For example, silicon tetrafluoride (SiF₄) generated after decomposition of the deposited products by cleaning is highly volatile, so that it is exhausted by the vacuum pump 400 through the exhaust pipes 150 and 152.

However, it may be difficult for the F radicals to reach portions of the exhaust pipes 150 and 152 distant from the film forming chamber 202, and cleaning performance may be degraded. In particular, since a pressure is lowered at a position close to a suction port of the vacuum pump 400, a cleaning rate may be lowered. As a result, the exhaust pipes 150 and 152 may be closed by the deposited products. In addition, a gap between a rotor and a casing may be filled with the products deposited in the vacuum pump 400 to thereby enter an overload state, and the vacuum pump 400 may be stopped. Therefore, in the first embodiment, as shown in FIG. 1, an exhaust pipe device 100 is disposed at a position closer to the suction port of the vacuum pump 400 than the film forming chamber 202.

In FIG. 1, the exhaust pipe device 100 according to the first embodiment is used as a part of an exhaust pipe including the exhaust pipes 150 and 152 disposed between the film forming chamber 202 and the vacuum pump 400 for exhausting the film forming chamber 202. The exhaust pipe device 100 includes a pipe body 102, a coil 104, an inner pipe 190 (dielectric pipe) being a dielectric, and a plasma generation circuit 106. For the pipe body 102, for example, a pipe material made of the same material as the normal exhaust pipes 150 and 152 is used. For example, stainless steel such as SUS304 is used. However, as the material of the pipe body 102, SUS316 steel is more preferably used from the viewpoint of corrosion resistance to cleaning gas. Further, for the pipe body 102, for example, a pipe material having the same size as the normal exhaust pipes 150 and 152 is used. However, the present disclosure is not limited thereto. The pipe body 102 may be a pipe having a size larger than the sizes of the exhaust pipes 150 and 152. Alternatively, the pipe body 102 may be a pipe having a size smaller than the sizes of the exhaust pipes 150 and 152.

Flanges are disposed at both ends of the pipe body 102, one end of the pipe body 102 is connected to the exhaust pipe 150 on which a flange having the same size is disposed, and the other end thereof is connected to the exhaust pipe 152 on which a flange having the same size is disposed. In FIG. 1, illustration of a clamp or the like for fixing the flange of the exhaust pipe device 100 and the respective flanges of the exhaust pipes 150 and 152 is omitted. Hereinafter, the same is applied to the respective drawings. Further, illustration of a sealing material such as an O-ring used for connection with the exhaust pipes 150 and 152 is omitted. In each of the embodiments to be described below, a case where the exhaust pipe 152 is interposed between the exhaust pipe device 100 and the vacuum pump 400 is shown. However, the present disclosure is not limited thereto. The exhaust pipe device 100 may be disposed directly at the suction port of the vacuum pump 400. The coil 104 and the inner pipe 190 made of the dielectric are disposed inside the pipe body 102.

The plasma generation circuit 106 uses the coil 104 to generate inductively coupled plasma inside the inner pipe 190 made of the dielectric, in the pipe body 102.

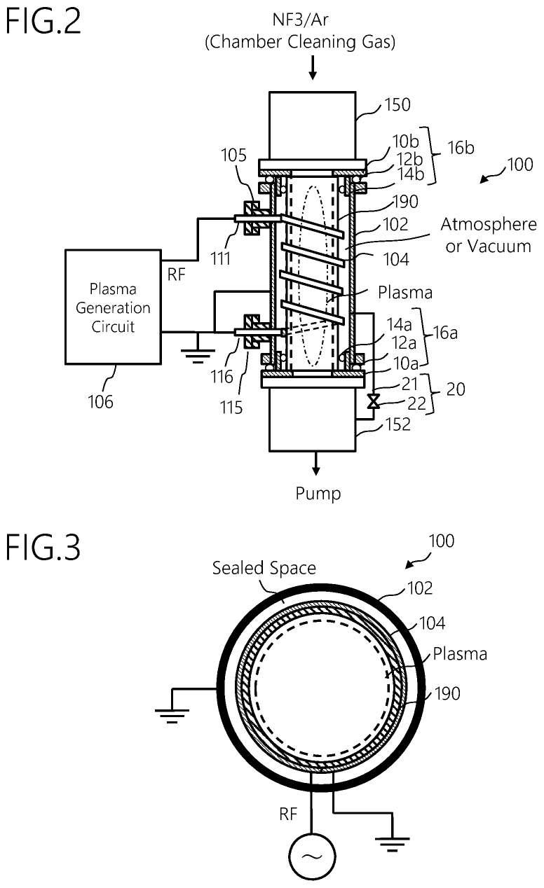

FIG. 2 is a cross-sectional view of an example of the exhaust pipe device in the first embodiment when viewed from a front direction. FIG. 3 is a cross-sectional view of an example of the exhaust pipe device in the first embodiment when viewed from a top surface direction. In FIG. 2, a cross-sectional structure shows a part of the exhaust pipe device 100 and the rest of the structure does not show a cross-section. Further, for the exhaust pipe device 100, cross-sections of the coil 104 and the inner pipe 190 inside the pipe body 102 are not shown. Hereinafter, the same is applied to each cross-sectional view viewed from the front direction. In FIGS. 2 and 3, the coil 104 is disposed inside the pipe body 102. In addition, the inner pipe 190 being the dielectric is disposed inside the coil 104. The inner pipe 190 is formed in the same type of shape as that of the pipe body 102. In the examples of FIGS. 2 and 3, for the cylindrical (annular) pipe body 102 having a circular cross-section, the cylindrical (annular) inner pipe 190 having the same type of circular cross-section is used. In addition, for the cylindrical pipe body 102 having a rectangular cross-section, the cylindrical inner pipe 190 having the same type of rectangular cross-section may be used.

The inner pipe 190 is disposed so as to form a space between an inner wall of the pipe body 102 and the inner pipe 190. The material of the dielectric being the inner pipe 190 may be a material having a dielectric constant higher than that of air. As the material of the inner pipe 190, for example, quartz, alumina (Al₂O₃) , yttria (Y₂O₃), hafnia (HfO₂) , zirconia (ZrO₂) , magnesium oxide (MgO), or aluminum nitride (AlN) is preferably used. The thickness of the inner pipe 190 may be appropriately set as long as it does not hinder the exhaust performance.

As shown in FIGS. 2 and 3, in the pipe body 102, the conductive coil 104 is spirally wound on the outer circumferential side of the inner pipe 190. The coil 104 is preferably disposed to contact the inner pipe 190. However, the present disclosure is not limited thereto.

In the examples of FIGS. 2 and 3, a radio-frequency (RF) electric field is applied to one of both ends of the coil 104. The other of both ends of the coil 104 is grounded (or connected to the ground potential). The other of both ends of the coil 104 may be grounded via a capacitor, not directly. Further, the pipe body 102 formed of a conductive member such as stainless steel is also grounded (or connected to the ground potential).

Specifically, an introduction terminal 111 (an example of a radio-frequency introduction terminal) is introduced into the pipe body 102 from an introduction terminal port 105 connected to an outer circumferential surface of the pipe body 102, and the introduction terminal 111 is connected to one of both ends of the coil 104. The introduction terminal 111 is used to apply a radio-frequency electric field to one of both ends of the coil 104. Further, an introduction terminal 116 is introduced into the pipe body 102 from an introduction terminal port 115 connected to the outer circumferential surface of the pipe body 102, and the introduction terminal 116 is connected to the other of both ends of the coil 104. The introduction terminal 116 is used to apply a ground potential to the other of both ends of the coil. In FIG. 2, the introduction terminal ports 105 and 115 are illustrated in a simplified manner. Hereinafter, the same is applied to the respective drawings.

Then, the plasma generation circuit 106 uses the coil 104 to generate plasma inside the inner pipe 190. The plasma generation circuit 106 applies a radio-frequency voltage between both ends of the coil 104. Specifically, the plasma generation circuit 106 applies a radio-frequency (RF) voltage to one of both ends of the coil 104 via the introduction terminal 111 with the pipe body 102 and the other of both ends of the coil 104 grounded, thereby generating inductively coupled plasma (ICP) in the dielectric inner pipe 190 disposed inside the coil 104.

Further, in a cleaning step, since the above-described cleaning gas such as NF₃ gas is supplied on the upstream side, the rest thereof is used to generate F radicals by the plasma inside the inner pipe 190. Then, the products deposited inside the inner pipe 190 are removed by the F radicals. As a result, high cleaning performance can be exhibited in the exhaust pipe.

Thereafter, for example, SiF₄ generated after decomposition of the deposited products by the F radicals is highly volatile, so that it is exhausted by the vacuum pump 400 through the exhaust pipe 152. Further, a part of the radicals generated by the exhaust pipe device 100 enters the vacuum pump 400 through the exhaust pipe 152 and cleans the products deposited in the vacuum pump 400. As a result, an amount of the products deposited in the vacuum pump 400 can be reduced. For example, F radicals generated by plasma generated in a part of an inner wall surface on the lower end side of the inner pipe 190 can be caused to enter the vacuum pump 400 with small consumption inside the pipe body 102.

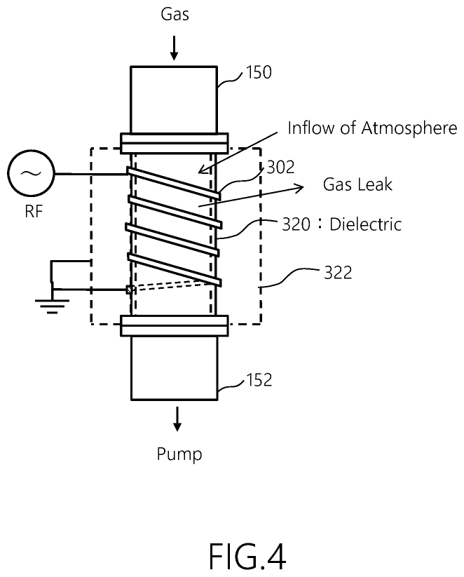

FIG. 4 is a front view of an example of an exhaust pipe device in a comparative example of the first embodiment. The comparative example of FIG. 4 shows a case where a coil 302 is wound around a pipe body 320 made of a dielectric. By applying a radio-frequency (RF) voltage to the coil 302, inductively coupled plasma is generated. Further, in the comparative example, the outer circumferential side of the coil 302 is covered with a metal cover 322 in order to shield a radio frequency. In the comparative example, when the dielectric is damaged by mechanical load or thermal stress, gas flowing through the exhaust pipe may not be blocked by the cover 322 to leak into the atmosphere, or the atmosphere may rush (flow) into the exhaust pipe to cause a failure of the vacuum pump on the downstream side. In particular, since the dielectric is more likely to be damaged as the diameter of the pipe is increased, a countermeasure against this is demanded.

On the other hand, in the first embodiment, as shown in FIG. 2, a space between the pipe body 102 and the inner pipe 190 is shielded from the atmosphere and a space inside the inner pipe 190, by sealing mechanisms 16a and 16b disposed at upper and lower ends of the pipe body 102. The sealing mechanisms 16a and 16b are preferably configured as follows, for example. The sealing mechanism 16a (16b) has a disk 10a (10b) having an opening in a center, an O-ring 12a (12b), and an O-ring 14a (14b). The O-ring 12a (12b) shields the space between the pipe body 102 and the inner pipe 190 from the atmosphere. The O-ring 14a (14b) shields the space between the pipe body 102 and the inner pipe 190 from the space inside the inner pipe 190. In the example of FIG. 2, the disk 10a (10b) is shown to have a thickness of about half the thickness of the flange of the pipe body 102 for easier understanding of the description. However, the disk 10a (10b) is preferably formed to have a thickness sufficiently smaller than the thickness of the flange of the pipe body 102. In such a case, the flange of the pipe body 102 and the flange of the pipe 150 are clamped with the disk 10b interposed therebetween. Similarly, the flange of the pipe body 102 and the flange of the pipe 152 are clamped with the disk 10a interposed therebetween. However, the present disclosure is not limited thereto. The disk 10a (10b) may be fixed to the flange of the pipe body 102 and the flange of the pipe 152 (150), respectively.

In the disk 10a, a ring-shaped convex portion is formed on the surface of the side (upstream side) of the pipe body 102 in the two surfaces of the upstream and downstream sides. Similarly, in the disk 10b, a ring-shaped convex portion is formed on the surface of the side (downstream side) of the pipe body 102 in the two surfaces of the upstream and downstream sides. Each ring-shaped convex portion is inserted and disposed in the space between the pipe body 102 and the inner pipe 190.

Therefore, an inner diameter of the convex portion is larger than an outer diameter of the inner pipe 190, and an outer diameter of the convex portion is smaller than an inner diameter of the pipe body 102.

On the lower side of the pipe body 102, the pipe body 102 is connected to the disk 10a via the O-ring 12a. The atmosphere inside the pipe body 102 is shielded from the atmosphere by the O-ring 12a. Further, the inner pipe 190 is supported on the disk 10a, and the O-ring 14a is disposed between the outer circumference of the inner pipe 190 and the ring-shaped convex portion of the disk 10a. As a result, the atmosphere inside the inner pipe 190 is shielded from the space between the pipe body 102 and the inner pipe 190 by the O-ring 14a. Similarly, on the upper side of the pipe body 102, the pipe body 102 is connected to the disk 10b via the O-ring 12b. The atmosphere inside the pipe body 102 is shielded from the atmosphere by the O-ring 12b. Further, an upper end face of the inner pipe 190 is covered with the disk 10b, and the O-ring 14b is disposed between the outer circumference of the inner pipe 190 and the ring-shaped convex portion of the disk 10b. As a result, the atmosphere inside the inner pipe 190 is shielded from the space between the pipe body 102 and the inner pipe 190 by the O-ring 14b.

The introduction terminal 111 is connected to one of both ends of the coil 104 in the space between the pipe body 102 and the inner pipe 109, which is shielded from the atmosphere and the space in the inner pipe 190, and applies a radio-frequency electric field to one of both ends when plasma is generated. Similarly, the introduction terminal 116 is connected to the other of both ends of the coil 104 in the space between the pipe body 102 and the inner pipe 190, which is shielded from the atmosphere and the space in the inner pipe 190, and applies (grounds) a ground potential to the other of both ends when plasma is generated.

Further, a bypass pipe 20 connected to the pipe 152 on the downstream side is connected to the outer circumferential side of the pipe body 102. In the bypass pipe 20, a valve 22 is disposed in the middle of a pipe 21. Then, in a state where the valve 22 is opened, the film forming chamber 202 is exhausted by the vacuum pump 400 before flowing the process gas into the film forming chamber 202, so that a pressure in the space between the pipe body 102 and the inner pipe 190 can be caused to become a pressure under vacuum. By closing the valve 22 in this state, the pressure in the space between the pipe body 102 and the inner pipe 190 can be maintained at a pressure under vacuum.

After that, a film forming process or the like is performed. As described above, since the space between the pipe body 102 and the inner pipe 190 is shielded from the atmosphere and the space inside the inner pipe 190 by the sealing mechanisms 16a and 16b, the cleaning gas or the like does not pass through the space between the pipe body 102 and the inner pipe 190. When plasma is generated in the exhaust pipe device 100, as described above, the cleaning gas or the like flows through the inner pipe 190, so that the pressure in the space between the pipe body 102 and the inner pipe 190 can be caused to be sufficiently lower than the pressure inside the inner pipe 190. As a result, it is possible to suppress plasma from being generated in the space between the pipe body 102 and the inner pipe 190. Note that the pressure in the space between the pipe body 102 and the inner pipe 190 is not limited to the above example. The pressure may be maintained at the atmospheric pressure. The plasma can be suppressed from being generated, even at the atmospheric pressure.

In the first embodiment, by forming a sealed double pipe structure of the pipe body 102 and the inner pipe 190 described above, even when the inner pipe 190 made of the dielectric is damaged, the gas flowing through the exhaust pipe can be prevented from leaking into the atmosphere. Similarly, it is possible to prevent the atmosphere from rushing (flowing) into the exhaust pipe. Note that, even when the space between the pipe body 102 and the inner pipe 190 is controlled to the atmospheric pressure, the volume of the space between the pipe body 102 and the inner pipe 190 is small, so that it is possible to prevent the inflow of the atmosphere enough to cause the damage of the vacuum pump 400.

As described above, according to the first embodiment, it is possible to remove the products deposited in the exhaust pipe near the vacuum pump 400 distant from the film forming chamber 202. Further, the products deposited in the vacuum pump 400 can be reduced. Further, an installation area of the device for removing the deposited products can be reduced.

### Second Embodiment

In the first embodiment, a configuration in which a space between a pipe body 102 and an inner pipe 190 is shielded from the atmosphere and a space inside the inner pipe 190 by sealing mechanisms 16a and 16b has been described. However, the present disclosure is not limited thereto. In a second embodiment, a configuration in which sealing is not performed between the space inside the pipe body 102 and the space inside the inner pipe 190 will be described. Further, points that are not particularly described below are the same as those in the first embodiment.

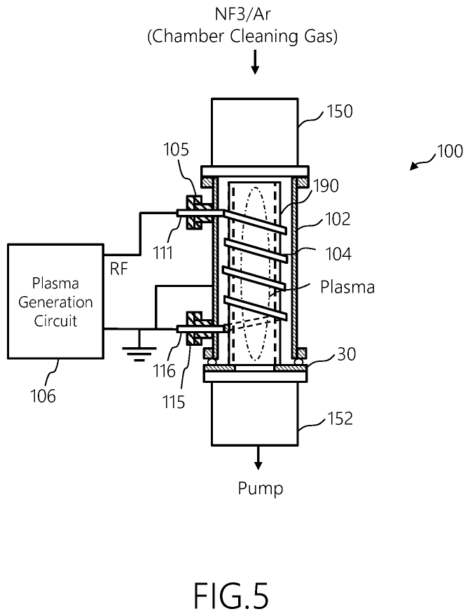

FIG. 5 is a cross-sectional view of an example of an exhaust pipe device in the second embodiment when viewed from a front direction. A cross-sectional view of an example of the exhaust pipe device in the second embodiment when viewed from a top surface direction is the same as that in FIG. 3. In the second embodiment, as shown in FIG. 5, a space between the pipe body 102 and the inner pipe 190 is not sealed with respect to a space where gas is exhausted. A coil 104 disposed between the pipe body 102 and the inner pipe 190 is preferably wound on the outer circumferential side of the inner pipe 190 in contact with the inner pipe 190, similarly to FIG. 3. However, in order to prevent electric discharge between the coil 104 and the inner pipe 190, a gap may be formed between the coil 104 and the inner pipe 190 in a case of a sheath length or less.

The inner pipe 190 is disposed in the space inside the pipe body 102. In the example of FIG. 5, an inner pipe support board 30 having an opening in a center is disposed below the pipe body 102, and the inner pipe 190 is supported on the inner pipe support board 30. Needless to say, an inner diameter of the inner pipe support board 30 is smaller than an outer diameter of the inner pipe 190. The pipe body 102 is clamped to a pipe 152 at a lower end with the inner pipe support board 30 interposed therebetween. The pipe body 102 is connected to a pipe 150 at an upper end.

Then, the plasma generation circuit 106 uses the coil 104 to generate plasma inside the inner pipe 190. Specifically, the plasma generation circuit 106 applies a radio-frequency (RF) voltage to one of both ends of the coil 104 via an introduction terminal 111 with the pipe body 102 and the other of both ends of the coil 104 grounded (or the other of both ends of the coil 104 is grounded via a capacitor), thereby generating inductively coupled plasma (ICP) in the dielectric inner pipe 190 disposed inside the coil 104. Then, the rest of the cleaning gas is used to generate F radicals by the plasma, and products deposited in the inner pipe 190 are removed by the F radicals. As a result, high cleaning performance can be exhibited in the exhaust pipe.

Thereafter, for example, SiF₄ generated after decomposition of the deposited products by the F radicals is highly volatile, so that it is exhausted by the vacuum pump 400 through the exhaust pipe 152. Further, by using a part of the radicals generated in an exhaust pipe device 100, the products deposited in the vacuum pump 400 are cleaned. As a result, an amount of the products deposited in the vacuum pump 400 can be reduced. For example, F radicals generated by plasma generated in a part of an inner wall surface on the lower end side of the inner pipe 190 can be caused to enter the vacuum pump 400 with small consumption inside the pipe body 102.

Here, a pressure outside the inner pipe 190 and a pressure inside the inner pipe 190 in the pipe body 102 are substantially the same, and products may also be deposited between the pipe body 102 and the inner pipe 190, similarly to an inner wall of the inner pipe 190. In the second embodiment, by disposing the inner pipe 190 made of the dielectric inside the coil 104 in which plasma is generated at a high density, even if the coil 104 is not covered with a dielectric or the like, it is possible to reduce degradation such as erosion of the coil 104 due to plasma. Further, since the products can be removed by the plasma inside the inner pipe 190, closing in the pipe can be avoided. The other contents are the same as those in the first embodiment.

Further, in the second embodiment, even when the inner pipe 190 being the dielectric is damaged, it is possible to prevent the gas flowing through the exhaust pipe from leaking into the atmosphere, by a double pipe structure of the pipe body 102 and the inner pipe 190. Similarly, it is possible to prevent the atmosphere from rushing (flowing) into the exhaust pipe.

As described above, according to the second embodiment, even when a space between double pipes is not sealed, similarly to the first embodiment, it is possible to remove the products deposited in the exhaust pipe near the vacuum pump 400 distant from the film forming chamber 202. Further, the products deposited in the vacuum pump 400 can be reduced. Further, an installation area of the device for removing the deposited products can be reduced.

### Third Embodiment

In a third embodiment, a configuration in which an ignition electrode is disposed on the upstream side of a plasma generation region will be described. Further, points that are not particularly described below are the same as those in the first embodiment.

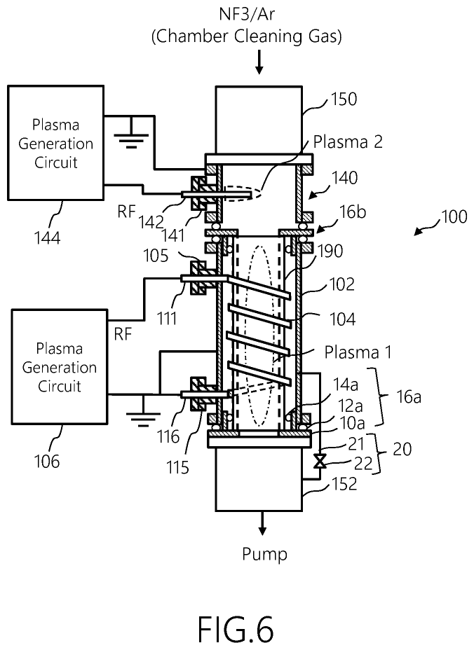

FIG. 6 is a cross-sectional view of an example of an exhaust pipe device in the third embodiment when viewed from a front direction. In an exhaust pipe device 100 according to the third embodiment, as shown in FIG. 6, a pipe 140 is disposed on the upper part (the upstream side) of a pipe body 102. An introduction electrode 142 (an example of an electrode) is introduced into the pipe 140 from an introduction terminal port 141 connected to an outer circumferential surface of the pipe 140, and a tip portion of the introduction electrode 142 is exposed inside the pipe 140. Here, the introduction electrode 142 is disposed on the upstream side of an inner pipe 190 with respect to the gas flow from the side of a film forming chamber. In the example of FIG. 6, the introduction electrode 142 is formed in a rod shape, and is disposed so as to extend in a direction substantially orthogonal to a direction in which the gas from the side of the film forming chamber flows. In the example of FIG. 6, a rod-shaped electrode is inserted, but the present disclosure is not limited thereto. A plate-shaped or hemispherical electrode is also suitable.

A plasma generation circuit 144 (radio-frequency circuit) generates plasma 2 on an exposed surface of the introduction electrode 142 in the pipe 140 by applying a radio-frequency (RF) voltage to the introduction electrode 142 with the pipe 140 grounded. The plasma generation circuit 144 applies a radio-frequency voltage having a Vpp(Peak-to-Peak Voltage) of 5 kV or more and a repetition frequency of 5 kHz or more to the introduction electrode 142. An applied voltage waveform is preferably a sine wave or a rectangular wave. This makes it to function as an ignition agent or a plasma maintenance stabilizer for plasma 1 generated in the inner pipe 190. The rest of structure is identical to those in FIGS. 2 and 3.

In the example of FIG. 6, the configuration in which the ignition introduction electrode 142 and the plasma generation circuit 144 are disposed on the upstream side with respect to the first embodiment has been described. However, the present disclosure is not limited thereto. A configuration in which the ignition introduction electrode 142 and the plasma generation circuit 144 are disposed on the upstream side with respect to the second embodiment is also suitable.

### Fourth Embodiment

A temperature of an inner pipe 190 being a dielectric increases due to plasma generation. In addition, the inner pipe 190 may be damaged due to the temperature increasing too high. Therefore, in a fourth embodiment, a configuration in which a cooling mechanism is further mounted on the configuration shown in FIG. 2 will be described. Further, points that are not particularly described below are the same as those in the first embodiment. The cooling mechanism in the fourth embodiment cools the inner pipe 190 by introducing a refrigerant into at least one of a space between a pipe body 102 and the inner pipe 190 and a member in the space. The details will be described below.

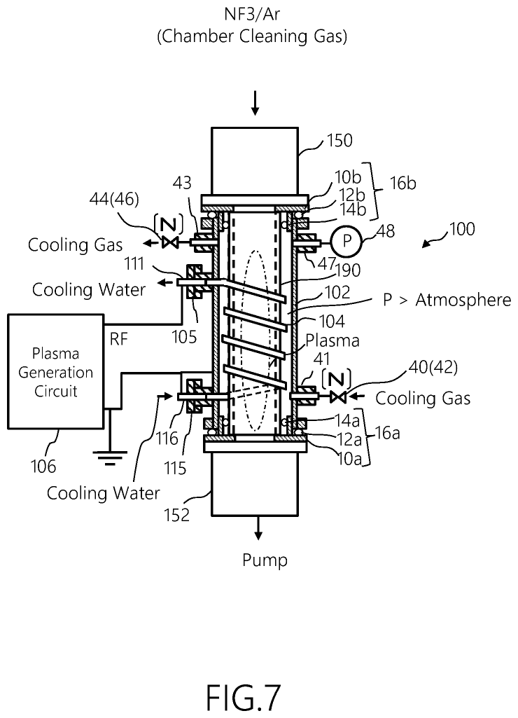

FIG. 7 is a cross-sectional view of an example of an exhaust pipe device in the fourth embodiment when viewed from a front direction. In the example of FIG. 7, a hollow pipe whose inside is hollow (hollow structure) is used as a member of a coil 104. Similarly, a hollow pipe whose inside is hollow is used as a member of each of two introduction terminals 111 and 116. As shown in FIG. 7, the cooling mechanism according to the fourth embodiment has the introduction terminal 116, the coil 104, and the introduction terminal 111 formed in the hollow structure.

One of both ends of the coil 104 is inserted into an introduction terminal port 105 from the inside. Further, the other of both ends of the coil 104 is inserted into an introduction terminal port 115 from the inside. The introduction terminal 111 is inserted from the introduction terminal port 105 connected to an outer circumferential surface of the pipe body 102, and is connected to one of both ends of the coil 104 inside the introduction terminal port 105. The introduction terminal 116 is inserted from the introduction terminal port 115 connected to the outer circumferential surface of the pipe body 102, and is connected to the other of both ends of the coil 104 inside the introduction terminal port 115. In the fourth embodiment, cooling water (an example of a refrigerant) is supplied from the introduction terminal 116 of the lower side to the inside of the coil 104, flows through the coil 104, and is exhausted from the introduction terminal 111 of the upper side.

Further, a wire for applying a radio-frequency (RF) voltage from a plasma generation circuit 106 is electrically connected to a surface of the introduction terminal 111. A wire for applying a ground potential from the plasma generation circuit 106 is electrically connected to a surface of the introduction terminal 116. Then, in a state in which the cooling water flows through the introduction terminal 116, the coil 104, and the introduction terminal 111, the plasma generation circuit 106 uses the coil 104 to generate plasma inside the inner pipe 190. The plasma generation circuit 106 applies a radio-frequency voltage between both ends of the coil 104.

Specifically, the plasma generation circuit 106 applies a radio-frequency (RF) voltage to one of both ends of the coil 104 via the introduction terminal 111 with the pipe body 102 and the other of both ends of the coil 104 grounded, thereby generating inductively coupled plasma (ICP) in the dielectric inner pipe 190 disposed inside the coil 104. At this time, the cooling water flowing through the coil 104 is used to cool the inner pipe 190, which is a dielectric whose temperature increases due to plasma generation, and the space between the inner pipe 109 and the pipe body 102. The inner pipe 109 is cooled by the cooling water, so that the inner pipe 109 can be suppressed from being damaged. Note that, from the viewpoint of cooling efficiency, the coil 104 is preferably disposed to contact the outer circumferential surface of the inner pipe 190.

Further, the cooling mechanism according to the fourth embodiment has a gas introduction port 41, a valve 40 (or a check valve 42), a gas exhaust port 43, and a valve 44 (or a check valve 46), as shown in FIG. 7. The cooling mechanism introduces cooling gas (another example of the refrigerant) from the gas introduction port 41 disposed on the lower side of the outer circumferential surface of the pipe body 102 into the space between the inner pipe 109 and the pipe body 102 via the valve 40 (or the check valve 42). Then, the cooling gas is exhausted to the outside from the gas exhaust port 43 disposed on the upper side of the outer circumferential surface of the pipe body 102 via the valve 44 (or the check valve 46). By flowing the cooling gas into the space between the inner pipe 109 and the pipe body 102, the inner pipe 190, which is the dielectric whose temperature increases due to plasma generation, and the space between the inner pipe 109 and the pipe body 102 are cooled. The inner pipe 109 is cooled by the cooling gas, so that the inner pipe 109 can be suppressed from being damaged. As the cooling gas, for example, air is used.

The cooling gas is introduced into the space between the inner pipe 109 and the pipe body 102 at a pressure higher than an atmospheric pressure. Therefore, a pressure in the space between the inner pipe 109 and the pipe body 102 is controlled to a pressure higher than a pressure in the space inside the inner pipe 109 and the atmospheric pressure. The pressure in the space between the inner pipe 109 and the pipe body 102 is measured by a pressure sensor 48 via a vent 47 disposed on the outer circumferential surface of the pipe body 102, and a pressure variation in the space is monitored. Here, when the inner pipe 190, which is the dielectric whose temperature increases due to plasma generation, is damaged, the cooling gas flows into the vacuum side and vacuum breakage occurs. Therefore, breakage of the inner pipe 190 is detected by the pressure sensor 48.

Specifically, when a pressure drop is detected by the pressure sensor 48, the valves 40 and 44 are controlled to be shut off. As a result, the inflow of the cooling gas into an exhaust line can be minimized. When the check valve 42 is used instead of the valve 40, the check valve 42 is used in which a cracking pressure is set so that the check valve 42 is shut off at a pressure in which a differential pressure between a primary pressure and a secondary pressure is a pressure higher than 0.1 MPa and which is lower than a supply pressure of the cooling gas. If the supply of the cooling gas is stopped at a supply source, the primary pressure (primary side of the check valve) is an atmospheric pressure, the secondary pressure (inside the pipe body 102) is the atmospheric pressure or less (pressure is lower than the atmospheric pressure due to damage), and the differential pressure is 0.1 MPa or less. For this reason, the cooling gas does not flow in a case of 0.1 MPa<cracking pressure<supply pressure. Therefore, if the supply of the cooling gas is stopped at the supply source in response to the detection of the damage of the inner pipe 190, the atmosphere can be prevented from flowing into the pipe body 102 even when the primary side is opened to the atmosphere. Further, in a case of using the check valve 46 instead of the valve 44, if the inner pipe 190 is damaged, the primary pressure becomes lower than the secondary pressure, so that a flow passage can be blocked. Therefore, the atmosphere can be prevented from flowing into the inside of the pipe body 102.

The rest of structure is identical to that in FIG. 2.

Note that, in the example of FIG. 7, the case of supplying and discharging the cooling water from the introduction terminals 116 and 111 has been described, but the present disclosure is not limited thereto. For example, the upper and lower flanges of the pipe body 102 may be formed in a hollow structure, and the cooling water may be supplied and discharged via the flanges. Further, a cooling mechanism for introducing only one of the cooling water and the cooling gas as the refrigerant for cooling the inner pipe 109 may be mounted.

The embodiments have been described above with reference to the specific examples. However, the present disclosure is not limited to these specific examples.

In addition, all exhaust pipe devices that include the elements of the present disclosure and can be appropriately changed in design by those skilled in the art are included in the scope of the present disclosure.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. An exhaust pipe device functioning as a part of an exhaust pipe disposed between a film forming chamber and a vacuum pump for exhausting an inside of the film forming chamber, the device comprising:
a pipe body;
a coil disposed inside the pipe body;
an inner pipe being a dielectric disposed inside the coil, and
a plasma generation circuit configured to generate plasma inside the inner pipe using the coil.

2. The device according to claim 1, wherein the coil is disposed to contact the inner pipe.

3. The device according to claim 1, further comprising:
an electrode disposed on an upstream side of the inner pipe with respect to a gas flow from a side of the film forming chamber; and
a radio-frequency circuit configured to apply a radio-frequency voltage to the electrode.

4. The device according to claim 3, wherein the radio-frequency circuit applies the radio-frequency voltage having a Vpp(Peak-to-Peak Voltage) of 5 kV or more and a repetition frequency of 5 kHz or more to the electrode.

5. The device according to claim 1, wherein the plasma generation circuit applies a radio-frequency voltage between both ends of the coil.

6. The device according to claim 5, wherein the plasma generation circuit applies the radio-frequency voltage between both ends of the coil with one of the both ends of the coil grounded.

7. The device according to claim 1, further comprising:
a first introduction terminal introduced from an outside of the pipe body to an inside of the pipe body and configured to apply a radio-frequency electric field to one of both ends of the coil; and
a second introduction terminal introduced from the outside of the pipe body to the inside of the pipe body and configured to apply a ground potential to another of both ends of the coil.

8. The device according to claim 1, wherein the pipe body is made of a conductive member.

9. The device according to claim 8, wherein a ground potential is applied to the pipe body.

10. The device according to claim 1, wherein the inner pipe is the dielectric having a dielectric constant higher than a dielectric constant of air.

11. The device according to claim 1, wherein the inner pipe has a same type of shape in cross-section as the pipe body.

12. The device according to claim 1, further comprising:
a sealing mechanism configured to shield a space between the pipe body and the inner pipe from atmosphere and a space inside the inner pipe.

13. The device according to claim 12, wherein the sealing mechanism has
a first O-ring shielding the space between the pipe body and the inner pipe from the atmosphere, and
a second O-ring shielding the space between the pipe body and the inner pipe from the space inside the inner pipe.

14. The device according to claim 12, wherein the coil is disposed in the space between the pipe body and the inner pipe, which is shielded from the atmosphere and the space inside the inner pipe.

15. The device according to claim 12, wherein gas from a side of the film forming chamber is exhausted through an inside of the inner pipe without passing through the space between the pipe body and the inner pipe.

16. The device according to claim 12, wherein a pressure of the space between the pipe body and the inner pipe is controlled to a pressure higher than a pressure of the space inside the inner pipe and an atmospheric pressure.

17. The device according to claim 1, further comprising: a cooling mechanism configured to introduce a refrigerant into at least one of a space between the pipe body and the inner pipe and a member in the space, and cool the inner pipe.

18. The device according to claim 17, wherein the coil is formed in a hollow structure, and
the cooling mechanism cools the inner pipe by flowing cooling water into the coil.

19. The device according to claim 17, wherein the cooling mechanism includes a gas introduction port and a gas exhaust port disposed in the pipe body, and
the cooling mechanism cools the inner pipe by flowing cooling gas into the space between the pipe body and the inner pipe through the gas introduction port and the gas exhaust port.

20. The device according to claim 19, wherein the cooling mechanism further includes a valve or a check valve, and a sensor, and
the cooling mechanism introduces the cooling gas into the space between the pipe body and the inner pipe via the valve or the check valve, and shuts off the valve or the check valve in a case that a pressure variation in the space is detected by the sensor.
